(19) United States
(12) Patent Application Publication
(10) Pub. No.: US 2023/0230845 A1
(43) Pub. Date: Jul. 20, 2023

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Koei KURIBAYASHI, Toyama (JP); Norikazu MIZUNO, Toyama (JP); Arito OGAWA, Toyama (JP)

(21) Appl. No.: 18/186,264

(22) Filed: Mar. 20, 2023

Related U.S. Application Data
(63) Continuation of application No. PCT/JP2020/035709, filed on Sep. 23, 2020.

(51) Int. Cl. H01L 21/3205; H01L 21/324; C23C 16/46

(52) U.S. Cl. CPC H01L 21/32051; H01L 21/324; C23C 16/46

(57) ABSTRACT

There is provided a technique that includes: (a) adjusting a temperature of a substrate to a first temperature; (b) forming a first molybdenum-containing film on the substrate by performing: (b1) supplying a molybdenum-containing gas to the substrate; and (b2) supplying a reducing gas to the substrate for a first time duration; (c) adjusting the temperature of the substrate to a second temperature after performing (b); and (d) forming a second molybdenum-containing film on the first molybdenum-containing film by performing: (d1) supplying the molybdenum-containing gas to the substrate; and (d2) supplying the reducing gas to the substrate for a second time duration.

### CROSS REFERENCE TO RELATED APPLICATIONS

This application is a bypass continuation application of PCT International Application No. PCT/JP2020/035709, filed on Sep. 23, 2020, in the WIPO, the entire contents of which are hereby incorporated by reference.

### TECHNICAL FIELD

The present disclosure relates to a substrate processing method, a method of manufacturing a semiconductor device, a non-transitory computer-readable recording medium and a substrate processing apparatus.

### BACKGROUND

For example, a tungsten film (W film) whose resistance is low is used as a word line of a NAND flash memory (or a DRAM) of a three-dimensional structure. For example, according to some related arts, a titanium nitride film (TiN film) or a molybdenum film (Mo film) serving as a barrier film may be formed between the W film and an insulating film.

However, in a case where a molybdenum-containing film is formed on a base film (or an underlying film) by using a molybdenum-containing gas and a reducing gas, when a film-forming process is performed at a high temperature, an element (or elements) contained in the base film may diffuse from the base film into the molybdenum-containing film. On the other hand, when a film-forming process is performed at a low temperature, it is possible to reduce a diffusion of the element (or elements) contained in the base film from the base film. However, a reaction between the molybdenum-containing gas and the reducing gas may become slow, and a supply time may be lengthened.

### SUMMARY

According to one embodiment of the present disclosure, there is provided a technique that includes: (a) adjusting a temperature of the substrate to a first temperature; (b) forming a first molybdenum-containing film on the substrate by performing: (b1) supplying a molybdenum-containing gas to the substrate; and (b2) supplying a reducing gas to the substrate for a first time duration, wherein (b1) and (b2) are performed one or more times after performing (a); (c) adjusting the temperature of the substrate to a second temperature after performing (b); and (d) forming a second molybdenum-containing film on the first molybdenum-containing film by performing: (d1) supplying the molybdenum-containing gas to the substrate; and (d2) supplying the reducing gas to the substrate for a second time duration, wherein (d1) and (d2) are performed one or more times after performing (c).

### BRIEF DESCRIPTION OF THE DRAWINGS

FIG. 1 is a diagram schematically illustrating a vertical cross-section of a vertical type process furnace of a substrate processing apparatus according to one or more embodiments of the technique of the present disclosure.

FIG. 2 is a diagram schematically illustrating a horizontal cross-section taken along a line A-A (in FIG. 1) of the vertical type process furnace of the substrate processing apparatus according to the embodiments of the technique of the present disclosure.

FIG. 3 is a block diagram schematically illustrating a configuration of a controller and related components of the substrate processing apparatus according to the embodiments of the technique of the present disclosure.

FIG. 4 is a flow chart schematically illustrating a substrate processing according to the embodiments of the technique of the present disclosure.

FIG. 5A is a diagram schematically illustrating a cross-section of a substrate before forming a first molybdenum-containing film on the substrate, FIG. 5B is a diagram schematically illustrating a cross-section of the substrate after forming the first molybdenum-containing film on the substrate, and FIG. 5C is a diagram schematically illustrating a cross-section of the substrate after forming a second molybdenum-containing film on the first molybdenum-containing film.

FIG. 6 is a diagram schematically illustrating a modified example of a second molybdenum-containing film forming step in the substrate processing according to the embodiments of the technique of the present disclosure.

### DETAILED DESCRIPTION

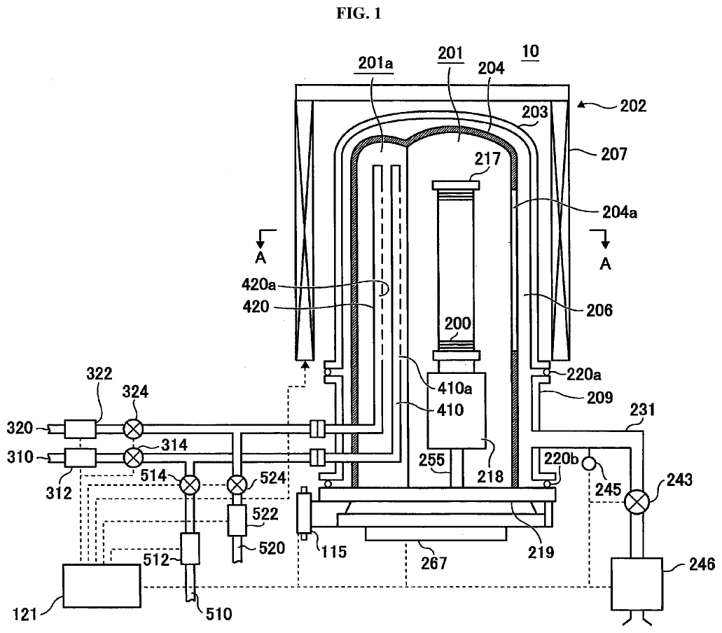

Hereinafter, one or more embodiments (also simply referred to as “embodiments”) according to the technique of the present disclosure will be described with reference to FIGS. 1 through 6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A substrate processing apparatus 10 according to the present embodiments includes a process furnace 202 provided with a heater 207 serving as a heating structure (which is a heating device or a heating system). The heater 207 is of a cylindrical shape, and is vertically installed while being supported by a heater base (not shown) serving as a support plate.

An outer tube 203 constituting a reaction vessel (which is a process vessel) is provided in an inner side of the heater 207 to be aligned in a manner concentric with the heater 207. For example, the outer tube 203 is made of a heat resistant material such as quartz (SiO₂) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the reaction vessel is provided in an inner side of the outer tube 203. For example, the inner tube 204 is made of a heat resistant material such as quartz (SiO2) and silicon carbide (SiC). The inner tube 204 is of a cylindrical shape with a closed upper end and an open lower end. The process vessel (reaction vessel) is constituted mainly by the outer tube 203, the inner tube 204 and the manifold 209. A process chamber 201 is provided in a hollow cylindrical portion of the process vessel (that is, an inside of the inner tube 204).

The process chamber 201 is configured to be capable of accommodating a plurality of wafers including a wafer 200 serving as a substrate in a horizontal orientation to be vertically arranged in a multistage manner by a boat 217 described later. Hereinafter, the plurality of wafers including the wafer 200 may also be simply referred to as wafers 200.

Nozzles 410 and 420 are installed in the process chamber 201 so as to penetrate a side wall of the manifold 209 and the inner tube 204. Gas supply pipes 310 and 320 are connected to the nozzles 410 and 420, respectively. However, the process furnace 202 of the present embodiments is not limited to the example described above.

Mass flow controllers (MFCs) 312 and 322 serving as flow rate controllers (flow rate control structures) and valves 314 and 324 serving as opening/closing valves are sequentially installed at the gas supply pipes 310 and 320 in this order from upstream sides to downstream sides of the gas supply pipes 310 and 320 in a gas flow direction, respectively. Gas supply pipes 510 and 520 through which an inert gas is supplied are connected to the gas supply pipes 310 and 320 at downstream sides of the valves 314 and 324, respectively. MFCs 512 and 522 serving as flow rate controllers (flow rate control structures) and valves 514 and 524 serving as opening/closing valves are sequentially installed at the gas supply pipes 510 and 520 in this order from upstream sides to downstream sides of the gas supply pipes 510 and 520 in the gas flow direction, respectively.

The nozzles 410 and 420 are connected to front ends (tips) of the gas supply pipes 310 and 320, respectively. Each of the nozzles 410 and 420 may include an L-shaped nozzle. Horizontal portions of the nozzles 410 and 420 are installed so as to penetrate the side wall of the manifold 209 and the inner tube 204. Vertical portions of the nozzles 410 and 420 are installed in a spare chamber 201a of a channel shape (a groove shape) protruding outward in a radial direction of the inner tube 204 and extending in a vertical direction. That is, the vertical portions of the nozzles 410 and 420 are installed in the spare chamber 201a toward the upper end of the inner tube 204 (in a direction in which the wafers 200 are arranged) and along an inner wall of the inner tube 204.

The nozzles 410 and 420 extend from a lower region of the process chamber 201 to an upper region of the process chamber 201. The nozzles 410 and 420 are provided with a plurality of gas supply holes 410a and a plurality of gas supply holes 420a facing the wafers 200, respectively. Thereby, a gas such as a process gas can be supplied to the wafers 200 through the gas supply holes 410a of the nozzle 410 and the gas supply holes 420a of the nozzle 420. The gas supply holes 410a and the gas supply holes 420a are provided from a lower portion to an upper portion of the inner tube 204. An opening area of each of the gas supply holes 410a and the gas supply holes 420a is the same, and each of the gas supply holes 410a and the gas supply holes 420a is provided at the same pitch. However, the gas supply holes 410a and the gas supply holes 420a are not limited thereto. For example, the opening area of each of the gas supply holes 410a and the gas supply holes 420a may gradually increase from the lower portion to the upper portion of the inner tube 204 to further uniformize a flow rate of the gas supplied through the gas supply holes 410a and the gas supply holes 420a.

The gas supply holes 410a of the nozzle 410 and the gas supply holes 420a of the nozzle 420 are provided from a lower portion to an upper portion of the boat 217 described later. Therefore, the process gas supplied into the process chamber 201 through the gas supply holes 410a and the gas supply holes 420a is supplied onto the wafers 200 accommodated in the boat 217 from the lower portion to the upper portion thereof, that is, an entirety of the wafers 200 accommodated in the boat 217. It is preferable that the nozzles 410 and 420 extend from the lower region to the upper region of the process chamber 201. However, the nozzles 410 and 420 may extend only to the vicinity of a ceiling of the boat 217.

A source gas serving as one of process gases is supplied into the process chamber 201 through the gas supply pipe 310 provided with the MFC 312 and the valve 314 and the nozzle 410.

A reducing gas serving as one of the process gases is supplied into the process chamber 201 through the gas supply pipe 320 provided with the MFC 322 and the valve 324 and the nozzle 420.

For example, as the inert gas, a rare gas such as argon (Ar) gas is supplied into the process chamber 201 through the gas supply pipes 510 and 520 provided with the MFCs 512 and 522 and the valves 514 and 524, respectively, and the nozzles 410 and 420. While the present embodiments will be described by way of an example in which the argon (Ar) is used as the inert gas, the inert gas according to the present embodiments is not limited thereto. For example, instead of the argon (Ar) gas or in addition to the argon (Ar) gas, a rare gas such as helium (He) gas, neon (Ne) gas and xenon (Xe) gas may be used as the inert gas.

A process gas supplier (which is a process gas supply structure or a process gas supply system) is constituted mainly by the gas supply pipes 310 and 320, the MFCs 312 and 322, the valves 314 and 324 and the nozzles 410 and 420. However, it is also possible for the nozzles 410 and 420 alone to be referred to as the process gas supplier. The process gas supplier may also be simply referred to as a “gas supplier” which is a gas supply structure or a gas supply system. When a molybdenum-containing gas (hereinafter, also referred to as a “Mo-containing gas”) is supplied through the gas supply pipe 310, a Mo-containing gas supplier (which is a Mo-containing gas supply structure or a Mo-containing gas supply system) is constituted mainly by the gas supply pipe 310, the MFC 312 and the valve 314. The Mo-containing gas supplier may further include the nozzle 410. Further, when the reducing gas is supplied through the gas supply pipe 320, a reducing gas supplier (which is a reducing gas supply structure or a reducing gas supply system) is constituted mainly by the gas supply pipe 320, the MFC 322 and the valve 324. The reducing gas supplier may further include the nozzle 420. In addition, an inert gas supplier (which is an inert gas supply structure or an inert gas supply system) is constituted mainly by the gas supply pipes 510 and 520, the MFCs 512 and 522 and the valves 514 and 524. Further, the inert gas supplier may also be referred to as a rare gas supplier (which is a rare gas supply structure or a rare gas supply system).

According to the present embodiments, the gas is supplied into a vertically long annular space which is defined by the inner wall of the inner tube 204 and edges (peripheries) of the wafers 200 through the nozzles 410 and 420 provided in the spare chamber 201a. The gas is ejected into the inner tube 204 through the gas supply holes 410a of the nozzle 410 and the gas supply holes 420a of the nozzle 420 facing the wafers 200. Specifically, gases such as the process gases are ejected into the inner tube 204 in a direction parallel to surfaces of the wafers 200 through the gas supply holes 410a of the nozzle 410 and the gas supply holes 420a of the nozzle 420, respectively.

An exhaust hole (which is an exhaust port) 204a is a through-hole facing the nozzles 410 and 420, and is provided at a side wall of the inner tube 204. For example, the exhaust hole 204a may be of a narrow slit-shaped through-hole elongating vertically. The gas supplied into the process chamber 201 through the gas supply holes 410a of the nozzle 410 and the gas supply holes 420a of the nozzle 420 flows over the surfaces of the wafers 200. The gas that has flowed over the surfaces of the wafers 200 is exhausted through the exhaust hole 204a into an exhaust path 206 configured by a gap provided between the inner tube 204 and the outer tube 203. The gas flowing in the exhaust path 206 flows into an exhaust pipe 231 and is then discharged (or exhausted) out of the process furnace 202.

The exhaust hole 204a is provided to face the wafers 200. The gas supplied in the vicinity of the wafers 200 in the process chamber 201 through the gas supply holes 410a and the gas supply holes 420a flows in a horizontal direction. The gas that has flowed in the horizontal direction is exhausted through the exhaust hole 204a into the exhaust path 206. The exhaust hole 204a is not limited to the slit-shaped through-hole. For example, the exhaust hole 204a may be configured as a plurality of holes.

The exhaust pipe 231 through which an inner atmosphere of the process chamber 201 is exhausted is installed at the manifold 209. A pressure sensor 245 serving as a pressure detector (pressure detecting structure) configured to detect an inner pressure of the process chamber 201, an APC (Automatic Pressure Controller) valve 243 and a vacuum pump 246 serving as a vacuum exhaust apparatus are sequentially connected to the exhaust pipe 231 in this order from an upstream side to a downstream side of the exhaust pipe 231. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. An exhauster (which is an exhaust structure or an exhaust system) is constituted mainly by the exhaust hole 204a, the exhaust path 206, the exhaust pipe 231, the APC valve 243 and the pressure sensor 245. The exhauster may further include the vacuum pump 246.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201 or transferred (unloaded) out of the process chamber 201. The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201.

The boat 217 serving as a substrate retainer is configured to accommodate (or support) the wafers 200 (for example, 25 to 200 wafers) while the wafers 200 are horizontally oriented with their centers aligned with one another with a predetermined interval therebetween in a multistage manner. For example, the boat 217 is made of a heat resistant material such as quartz and SiC. A plurality of heat insulating plates 218 horizontally oriented are provided under the boat 217 in a multistage manner (now shown). Each of the heat insulating plates 218 is made of a heat resistant material such as quartz and SiC. With such a configuration, the heat insulating plates 218 suppress the transmission of the heat from the heater 207 to the seal cap 219. However, the present embodiments are not limited thereto. For example, instead of the heat insulating plates 218, a heat insulating cylinder (not shown) such as a cylinder made of a heat resistant material such as quartz and SiC may be provided under the boat 217.

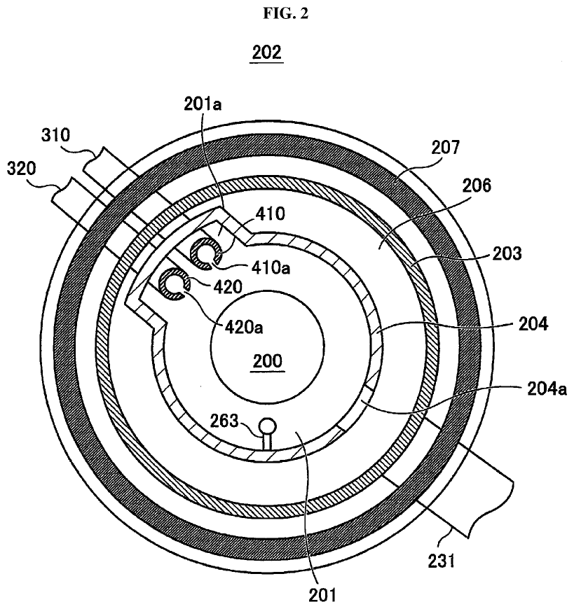

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201 can be obtained. Similar to the nozzles 410 and 420, the temperature sensor 263 is L-shaped, and is provided along the inner wall of the inner tube 204.

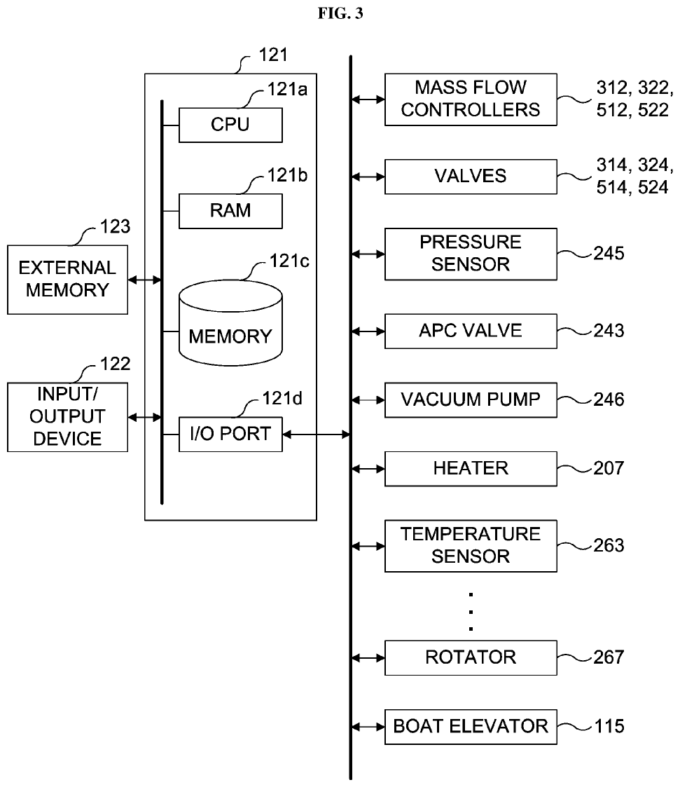

As shown in FIG. 3, a controller 121 serving as a control device (or a control structure) is constituted by a computer including a CPU (Central Processing Unit) 121a, a RAM (Random Access Memory) 121b, a memory 121c and an I/O port 121d. The RAM 121b, the memory 121c and the I/O port 121d may exchange data with the CPU 121a through an internal bus (not shown). For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on sequences and conditions of a method of manufacturing a semiconductor device described later is readably stored in the memory 121c. The process recipe is obtained by combining steps of the method of manufacturing the semiconductor device described later such that the controller 121 can execute the steps to acquire a predetermined result, and functions as a program. Hereafter, the process recipe and the control program may be collectively or individually referred to as a “program”. In the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components described above such as the MFCs 312, 322, 512 and 522, the valves 314, 324, 514 and 524, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 512 and 522, opening and closing operations of the valves 314, 324, 514 and 524, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into a computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

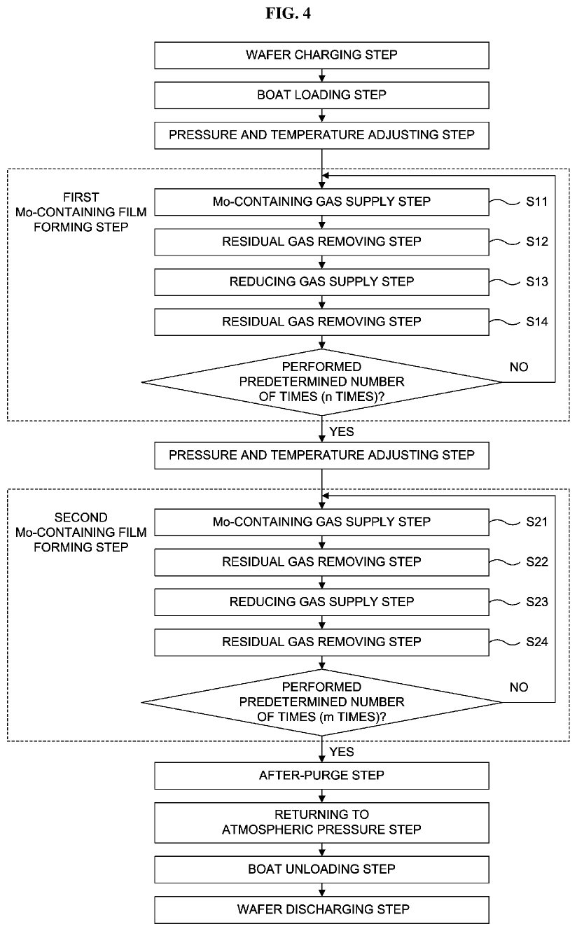

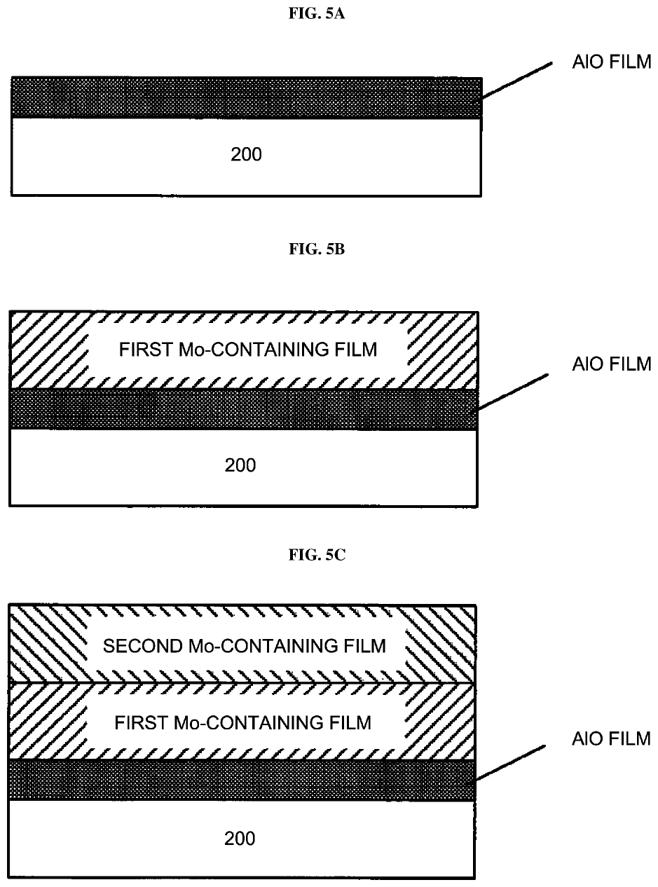

Hereinafter, as a part of a manufacturing process of a semiconductor device, an exemplary sequence of a substrate processing of forming a film containing molybdenum (Mo) (that is, a molybdenum-containing film) on the wafer 200 will be described with reference to FIGS. 4, 5A, 5B and 5C. Hereinafter, the molybdenum-containing film may also be simply referred to as a “Mo-containing film”. For example, the Mo-containing film is used as a control gate electrode of a NAND flash memory of a three-dimensional structure. According to the present embodiments, for example, as shown in FIG. 5A, an aluminum oxide film (hereinafter, also simply referred to as an “AlO film”) serving as a metal-containing film containing aluminum (Al) (which is a non-transition metal element) and also serving as a metal oxide film is formed on the surface of the wafer 200 in advance. The substrate processing of forming the Mo-containing film is performed by using the process furnace 202 of the substrate processing apparatus 10 described above. In the following description, operations of the components constituting the substrate processing apparatus 10 are controlled by the controller 121.

The substrate processing (that is, the manufacturing process of the semiconductor device) according to the present embodiments may include: (a) adjusting a temperature of the wafer 200 to a first temperature; (b) forming a first molybdenum-containing film on the wafer 200 by performing: (b1) supplying a molybdenum-containing gas to the wafer 200; and (b2) supplying a reducing gas to the wafer 200 for a first time duration, wherein (b1) and (b2) are performed one or more times after performing (a); (c) adjusting the temperature of the wafer 200 to a second temperature after performing (b); and (d) forming a second molybdenum-containing film on the first molybdenum-containing film by performing: (d1) supplying the molybdenum-containing gas to the substrate; and (d2) supplying the reducing gas to the substrate for a second time duration, wherein (d1) and (d2) are performed one or more times after performing (c).

Further, the second temperature is higher than the first temperature, and the second time duration is shorter than the first time duration.

In the present specification, the term “wafer” may refer to “a wafer itself”, may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, may refer to “a surface of a predetermined layer or a film formed on a wafer”. In the present specification, the term “substrate” and “wafer” may be used as substantially the same meaning.

### <Wafer Charging Step and Boat Loading Step>

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 to be accommodated in the process vessel (boat loading step). With the boat 217 loaded, the seal cap 219 seals a lower end opening of the outer tube 203 (that is, the lower end opening of the manifold 209) via the O-ring 220b.

### <Pressure and Temperature Adjusting Step>

The vacuum pump 246 vacuum-exhausts the inner atmosphere of the process chamber 201 such that the inner pressure of the process chamber 201 (that is, a pressure in a space in which the wafers 200 are accommodated) reaches and is maintained at a desired pressure (vacuum degree). Meanwhile, the inner pressure of the process chamber 201 is measured by the pressure sensor 245, and the APC valve 243 is feedback-controlled based on measured pressure information (pressure adjusting step). Further, the vacuum pump 246 continuously vacuum-exhausts the inner atmosphere of the process chamber 201 until at least a processing of the wafer 200 is completed.

In addition, the heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). Further, the heater 207 continuously heats the process chamber 201 until at least the processing of the wafer 200 is completed. However, a temperature of the heater 207 is adjusted to an appropriate temperature such that a temperature of the wafer 200 reaches and is maintained at the first temperature within a range equal to or higher than 445° C. and equal to or lower than 505° C. until a first Mo-containing film forming step described later is completed.

### <First Mo-Containing Film Forming Step>

The first Mo-containing film forming step is performed by performing steps S11 through S14 described below.

### <Mo-Containing Gas Supply Step S11>

The valve 314 is opened to supply the Mo-containing gas (serving as the source gas) into the gas supply pipe 310. A flow rate of the Mo-containing gas supplied into the gas supply pipe 310 is adjusted by the MFC 312. The Mo-containing gas whose flow rate is adjusted is then supplied into the process chamber 201 through the gas supply holes 410a of the nozzle 410, and is exhausted through the exhaust pipe 231. Thereby, the Mo-containing gas is supplied to the wafers 200. In the present step, in parallel with a supply of the Mo-containing gas, the valve 514 is opened to supply the inert gas such as the argon (Ar) gas into the gas supply pipe 510. A flow rate of the argon gas supplied into the gas supply pipe 510 is adjusted by the MFC 512. The argon gas whose flow rate is adjusted is then supplied into the process chamber 201 together with the Mo-containing gas, and is exhausted through the exhaust pipe 231. In the present step, in order to prevent the Mo-containing gas from entering the nozzle 420, the valve 524 may be opened to supply the argon gas into the gas supply pipe 520. The argon gas is then supplied into the process chamber 201 through the gas supply pipe 320 and the nozzle 420, and is exhausted through the exhaust pipe 231.

In the present step, for example, the APC valve 243 is appropriately adjusted (or controlled) such that the inner pressure of the process chamber 201 can be set to a pressure within a range from 1 Pa to 3,990 Pa. For example, the inner pressure of the process chamber 201 is set to 1,000 Pa by adjusting the APC valve 243. For example, a supply flow rate of the Mo-containing gas controlled by the MFC 312 can be set to a flow rate within a range from 0.1 slm to 1.0 slm, preferably from 0.1 slm to 0.5 slm. For example, a supply flow rate of the argon gas controlled by each of the MFCs 512 and 522 can be set to a flow rate within a range from 0.1 slm to 20 slm. In the present specification, a notation of a numerical range such as “from 1 Pa to 3,990 Pa” means that a lower limit and an upper limit are included in the numerical range. Therefore, for example, the numerical range “from 1 Pa to 3,990 Pa” means a range equal to or higher than 1 Pa and equal to or lower than 3,990 Pa. The same also applies to other numerical ranges described herein.

In the present step, the Mo-containing gas and the argon gas are supplied into the process chamber 201 without supplying other gases thereto. According to the present embodiments, for example, a gas containing molybdenum (Mo) and oxygen (O) (that is, the Mo-containing gas) may be used as the source gas. For example, a gas such as molybdenum dichloride dioxide (MoO2Cl2) gas and molybdenum oxide tetrachloride (MoOCl4) gas may be used as the Mo-containing gas. The present embodiments will be described by way of an example in which the MoO2Cl2 gas is used as the Mo-containing gas. By supplying the MoO2Cl2 gas, a molybdenum-containing layer (also simply referred to as a “Mo-containing layer”) is formed on the wafer 200 (that is, on the AlO film serving as a base film on the surface of the wafer 200). The Mo-containing layer may refer to a molybdenum layer containing chlorine (Cl) or oxygen (O), may refer to an adsorption layer of MoO2Cl2, or may refer to both of the molybdenum layer containing chlorine (Cl) or oxygen (O) and the adsorption layer of the MoO2Cl2.

### <Residual Gas Removing Step S12>

After a predetermined time (for example, from 1 second to 60 seconds) has elapsed from the supply of the Mo-containing gas, the valve 314 of the gas supply pipe 310 is closed to stop the supply of the Mo-containing gas. That is, for example, a supply time (which is a time duration) of supplying the Mo-containing gas to the wafer 200 is set to a time within a range from 1 second to 60 seconds. In the present step, with the APC valve 243 of the exhaust pipe 231 open, the vacuum pump 246 vacuum-exhausts the inner atmosphere of the process chamber 201 to remove a residual gas remaining in the process chamber 201 such as a residual Mo-containing gas which did not react or which contributed to a formation of the Mo-containing layer from the process chamber 201. That is, the process chamber 201 is purged. In the present step, by maintaining the valves 514 and 524 open, the argon gas is continuously supplied into the process chamber 201. The argon gas serves as a purge gas, which improves an efficiency of removing the residual gas remaining in the process chamber 201 such as the residual Mo-containing gas which did not react or which contributed to the formation of the Mo-containing layer out of the process chamber 201.

### <Reducing Gas Supply Step S13>

After the residual gas remaining in the process chamber 201 is removed, the valve 324 is opened to supply the reducing gas into the gas supply pipe 320. A flow rate of the reducing gas supplied into the gas supply pipe 320 is adjusted by the MFC 322. The reducing gas whose flow rate is adjusted is then supplied into the process chamber 201 through the gas supply holes 420a of the nozzle 420, and is exhausted through the exhaust pipe 231. Thereby, in the present step, the reducing gas is supplied to the wafer 200. In the present step, in parallel with a supply of the reducing gas, the valve 524 is opened to supply the argon gas into the gas supply pipe 520. The flow rate of the argon gas supplied into the gas supply pipe 520 is adjusted by the MFC 522. The argon gas whose flow rate is adjusted is then supplied into the process chamber 201 together with the reducing gas, and is exhausted through the exhaust pipe 231. In the present step, in order to prevent the reducing gas from entering the nozzle 410, the valve 514 may be opened to supply the argon gas into the gas supply pipe 510. The argon gas is then supplied into the process chamber 201 through the gas supply pipe 310 and the nozzle 410, and is exhausted through the exhaust pipe 231.

In the present step, for example, the APC valve 243 is appropriately adjusted (or controlled) such that the inner pressure of the process chamber 201 can be set to a pressure within a range from 1 Pa to 3,990 Pa. For example, the inner pressure of the process chamber 201 is set to 2,000 Pa by adjusting the APC valve 243. For example, a supply flow rate of the reducing gas controlled by the MFC 322 can be set to a flow rate within a range from 1 slm to 50 slm, preferably from 15 slm to 30 slm. For example, the supply flow rate of the argon gas controlled by each of the MFCs 512 and 522 can be set to a flow rate within a range from 0.1 slm to 30 slm. For example, a supply time (which is a time duration) of supplying the reducing gas to the wafer 200 is set to a first time duration within a range from 5 minutes to 30 minutes. For example, the supply time of supplying the reducing gas to the wafer 200 is set to 20 minutes. By supplying the reducing gas to the wafer 200 for 5 minutes or more, it is possible to reduce the Mo-containing gas adsorbed on the wafer 200. Further, by supplying the reducing gas to the wafer 200 for 30 minutes or less, it is possible to improve a throughput. Thereby, it is possible to ensure a certain productivity.

In the present step, the reducing gas and the argon gas are supplied into the process chamber 201 without supplying other gases thereto. According to the present embodiments, for example, a hydrogen-containing gas such as hydrogen (H2) gas, deuterium (D2) gas and a gas containing activated hydrogen may be used as the reducing gas. The present embodiments will be described by way of an example in which the H2 gas is used as the reducing gas. When the H2 gas is used as the reducing gas, a substitution reaction occurs between the H2 gas and at least a portion of the Mo-containing layer formed on the wafer 200 in the step S11. That is, oxygen (O) or chlorine (Cl) in the Mo-containing layer reacts with H2, desorbs from the Mo-containing layer, and is discharged from the process chamber 201 as reaction by-products such as water vapor (H2O), hydrogen chloride (HCl) and chlorine (Cl2). Thereby, the Mo-containing layer containing molybdenum (Mo) and substantially free of chlorine (Cl) and oxygen (O) is formed on the wafer 200.

### <Residual Gas Removing Step S14>

After the Mo-containing layer is formed, the valve 324 of the gas supply pipe 320 is closed to stop the supply of the reducing gas. Then, a residual gas remaining in the process chamber 201 such as a residual reducing gas which did not react or which contributed to a formation of the Mo-containing layer and the reaction by-products are removed out of the process chamber 201 in substantially the same manners as in the step S12 described later. That is, the process chamber 201 is purged.

### <Performing a Predetermined Number of Times>

By performing a cycle (in which the step S11 through the step S14 described above are sequentially performed in this order) at least once (that is, a predetermined number of times (n times)), the first Mo-containing film of a predetermined thickness (for example, from 1 nm to 5 nm) is formed on the wafer 200 where the AlO film is formed on the surface thereof as shown in FIG. 5B. It is preferable that the cycle described above is repeatedly performed a plurality number of times.

For example, a surface roughness of the Mo-containing film formed by heating the wafer 200 to the temperature lower than 445° C. or higher than 505° C. may deteriorate as compared with that of the Mo-containing film formed by heating the wafer 200 to the temperature within a range from 445° C. to 505° C. Further, an amount of a diffusion of aluminum (Al) from the AlO film serving as the base film to the Mo-containing film formed by heating the wafer 200 to the temperature lower than 445° C. or higher than 505° C. is greater than the amount of the diffusion of aluminum (Al) from the AlO film serving as the base film to the Mo-containing film formed by heating the wafer 200 to the temperature within a range from 445° C. to 505° C. The reasons therefor may be surmised as follows. A reduction by the H2 gas supplied in the reducing gas supply step S13 is incomplete at the temperature lower than 445° C., so that the Mo-containing gas may be prevented from being reduced sufficiently. Thereby, MoOxCly is generated. Thus, the MoOxCly attacks the AlO film (that is, the base film) and the Mo-containing film formed as described above. In the present specification, the term “attack” may refer to the reduction. In addition, at the temperature higher than 505° C., it is believed that the HCl (which is generated as the reaction by-products due to the supply of the reducing gas in the reducing gas supply step S13) attacks the AlO film (that is, the base film) and the Mo-containing film formed as described above.

That is, by forming the first Mo-containing film on the wafer 200 where the AlO film is formed on the surface thereof in the first Mo-containing film forming step while setting the temperature of the wafer 200 to the temperature within a range equal to or higher than 445° C. and equal to or lower than 505° C., it is possible to suppress the diffusion of aluminum (Al) from the AlO film serving as the base film to the Mo-containing film (that is, the first Mo-containing film). That is, the first Mo-containing film is formed as a film capable of suppressing the diffusion of aluminum (Al) from the AlO film serving as the base film and whose resistance is low. Moreover, it is possible to form the first Mo-containing film whose average roughness (Ra) of the surface roughness is 1.0 nm or less, that is, whose surface roughness is acceptable.

### <Pressure and Temperature Adjusting Step>

After forming the first Mo-containing film with a predetermined thickness on the wafer 200, the argon gas (which is a rare gas serving as the inert gas) is supplied into the process chamber 201 through each of the gas supply pipes 510 and 520, and then is exhausted through the exhaust pipe 231. The argon gas serves as the purge gas, and the inner atmosphere of the process chamber 201 is purged with the inert gas. Thus, the residual gas remaining in the process chamber 201 or the reaction by-products remaining in the process chamber 201 is removed from the process chamber 201. Thereafter, the inner atmosphere of the process chamber 201 is replaced with the inert gas (substitution by inert gas). Then, the inner pressure of the process chamber 201 is measured by the pressure sensor 245 under an inert gas atmosphere, and the APC valve 243 is feedback-controlled based on the measured pressure information (pressure adjusting step). In the present step, for example, the APC valve 243 is appropriately adjusted (or controlled) such that the inner pressure of the process chamber 201 can be at least higher than the inner pressure of the process chamber 201 in the first Mo-containing film forming step and the inner pressure of the process chamber 201 in a second Mo-containing film forming step described later. For example, the inner pressure of the process chamber 201 is set to an atmospheric pressure. By elevating the inner pressure of the process chamber 201 higher than inner pressure of the process chamber 201 in a film-forming step (that is, the first Mo-containing film forming step) as described above, it is possible to increase a thermal conductivity and it is also possible to shorten a temperature elevation time. Further, the inner pressure of the process chamber 201 in the present step may be elevated to near the atmospheric pressure in order to increase the thermal conductivity. In addition, by using the rare gas in the present step, it is possible to suppress a change in surface properties of the first Mo-containing film. For example, when nitrogen (N2) gas (which is generally used as the inert gas) is used, the first Mo-containing film and N2 may react (or adsorb) with each other, which affects the surface properties of the first Mo-containing film. On the other hand, when the rare gas such as the argon gas is used, such a change in the surface properties of the first Mo-containing film can be suppressed.

In addition, in the present step, the heater 207 heats the process chamber 201 such that the inner temperature of the process chamber 201 reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201 is obtained (temperature adjusting step). In the following, for example, the temperature of the heater 207 is set such that the temperature of the wafer 200 reaches and is maintained at the second temperature (which is higher than the first temperature) within a range equal to or higher than 550° C. and equal to or lower than 590° C. For example, the second temperature is set to 580° C. That is, the temperature of the heater 207 is set such that the temperature of the wafer 200 reaches and is maintained at the second temperature within a range equal to or higher than 550° C. and equal to or lower than 590° C., for example, 580° C. until the second Mo-containing film forming step described later is completed.

When the N2 gas is used as the inert gas in the present step, the first Mo-containing film formed on the wafer 200 will be nitrided. According to the present embodiments of the present disclosure, by using the argon gas as the inert gas, it is possible to elevate the temperature of the wafer 200 without changing a surface state of the first Mo-containing film. Moreover, when elevating the temperature of the wafer 200, the reducing gas may be used. That is, the wafer 200 is heated from the first temperature to the second temperature in a reducing atmosphere. By elevating the temperature of the wafer 200 in the reducing atmosphere as described above, it is possible to elevate the temperature of the wafer 200 while removing by-products and impurities contained in the first Mo-containing film. That is, an annealing process can be performed while elevating the temperature of the wafer 200. By performing the annealing process, it is possible to remove at least the by-products and the impurities adsorbed on a surface of the first Mo-containing film.

### <Second Mo-Containing Film Forming Step>

The second Mo-containing film forming step is performed by performing steps S21 through S24 described below.

### <Mo-Containing Gas Supply Step S21>

The valve 314 is opened to supply the Mo-containing gas (serving as the source gas) into the gas supply pipe 310. The Mo-containing gas used in the second Mo-containing film forming step may be the same gas as the Mo-containing gas used in the first Mo-containing film forming step described above, or may be different from the Mo-containing gas used in the first Mo-containing film forming step. The flow rate of the Mo-containing gas supplied into the gas supply pipe 310 is adjusted by the MFC 312. The Mo-containing gas whose flow rate is adjusted is then supplied into the process chamber 201 through the gas supply holes 410a of the nozzle 410, and is exhausted through the exhaust pipe 231. Thereby, the Mo-containing gas is supplied to the wafers 200. In the present step, in parallel with the supply of the Mo-containing gas, the valve 514 is opened to supply the inert gas such as the argon gas into the gas supply pipe 510. The flow rate of the argon gas supplied into the gas supply pipe 510 is adjusted by the MFC 512. The argon gas whose flow rate is adjusted is then supplied into the process chamber 201 together with the Mo-containing gas, and is exhausted through the exhaust pipe 231. In the present step, in order to prevent the Mo-containing gas from entering the nozzle 420, the valve 524 may be opened to supply the argon gas into the gas supply pipe 520. The argon gas is then supplied into the process chamber 201 through the gas supply pipe 320 and the nozzle 420, and is exhausted through the exhaust pipe 231.

In the present step, for example, the APC valve 243 is appropriately adjusted (or controlled) such that the inner pressure of the process chamber 201 can be set to the pressure within a range from 1 Pa to 3,990 Pa. For example, the inner pressure of the process chamber 201 is set to 1,000 Pa by adjusting the APC valve 243. For example, the supply flow rate of the Mo-containing gas controlled by the MFC 312 can be set to the flow rate within a range from 0.1 slm to 1.0 slm, preferably from 0.1 slm to 0.5 slm. For example, a supply flow rate of the argon gas controlled by each of the MFCs 512 and 522 can be set to the flow rate within a range from 0.1 slm to 20 slm.

In the present step, the Mo-containing gas and the argon gas are supplied into the process chamber 201 without supplying other gases thereto. As described above, the present embodiments will be described by way of the example in which the MoO2Cl2 gas is used as the Mo-containing gas. By supplying the MoO2Cl2 gas serving as the Mo-containing gas, a Mo-containing layer is formed on the wafer 200 (that is, on the first Mo-containing film on the surface of the wafer 200). The Mo-containing layer may refer to a molybdenum layer containing chlorine (Cl) or oxygen (O), may refer to an adsorption layer of MoO2Cl2, or may refer to both of the molybdenum layer containing chlorine (Cl) or oxygen (O) and the adsorption layer of the MoO2Cl2.

### <Residual Gas Removing Step S22>

After the Mo-containing layer is formed, the valve 314 of the gas supply pipe 310 is closed to stop the supply of the Mo-containing gas. Then, the residual gas remaining in the process chamber 201 such as the Mo-containing gas which did not react or which contributed to the formation of the Mo-containing layer and the reaction by-products are removed out of the process chamber 201 in substantially the same manners as in the step S12. That is, the process chamber 201 is purged.

### <Reducing Gas Supply Step S23>

After the residual gas remaining in the process chamber 201 is removed, the valve 324 is opened to supply the reducing gas into the gas supply pipe 320. The flow rate of the reducing gas supplied into the gas supply pipe 320 is adjusted by the MFC 322. The reducing gas whose flow rate is adjusted is then supplied into the process chamber 201 through the gas supply holes 420a of the nozzle 420, and is exhausted through the exhaust pipe 231. Thereby, in the present step, the reducing gas is supplied to the wafer 200. In the present step, in parallel with the supply of the reducing gas, the valve 524 is opened to supply the argon gas into the gas supply pipe 520. The flow rate of the argon gas supplied into the gas supply pipe 520 is adjusted by the MFC 522. The argon gas whose flow rate is adjusted is then supplied into the process chamber 201 together with the reducing gas, and is exhausted through the exhaust pipe 231. In the present step, in order to prevent the reducing gas from entering the nozzle 410, the valve 514 may be opened to supply the argon gas into the gas supply pipe 510. The argon gas is then supplied into the process chamber 201 through the gas supply pipe 310 and the nozzle 410, and is exhausted through the exhaust pipe 231.

In the present step, for example, the APC valve 243 is appropriately adjusted (or controlled) such that the inner pressure of the process chamber 201 can be set to a pressure within a range from 1 Pa to 3,990 Pa. For example, the inner pressure of the process chamber 201 is set to 2,000 Pa by adjusting the APC valve 243. For example, the supply flow rate of the reducing gas controlled by the MFC 322 can be set to a flow rate within a range from 1 slm to 50 slm, preferably from 15 slm to 30 slm. For example, the supply flow rate of the argon gas controlled by each of the MFCs 512 and 522 can be set to a flow rate within a range from 0.1 slm to 30 slm. When the H2 gas is used as the reducing gas, a supply time (which is a time duration) of supplying the H2 gas to the wafer 200 is set to the second time duration (which is shorter than the first time duration) within a range from 10 seconds to 5 minutes. For example, the supply time of supplying the H2 gas to the wafer 200 is set to 1 minute. By supplying the H2 gas to the wafer 200 for 10 seconds or more, it is possible to promote the reduction of the Mo-containing gas adsorbed on the wafer 200. Further, by supplying the H2 gas to the wafer 200 for 5 minutes or less, it is possible to ensure the productivity.

In the present step, the H2 gas and the argon gas are supplied into the process chamber 201 without supplying other gases thereto. The substitution reaction occurs between the H2 gas and at least a portion of the Mo-containing layer formed on the wafer 200 in the step S21. That is, oxygen (O) or chlorine (Cl) in the Mo-containing layer reacts with the H2, desorbs from the Mo-containing layer, and is discharged from the process chamber 201 as the reaction by-products such as water vapor (H2O), hydrogen chloride (HCl) and chlorine (Cl2). Thereby, the Mo-containing layer containing molybdenum (Mo) and substantially free of chlorine (Cl) and oxygen (O) is formed on the wafer 200.

In the present step, when the temperature of the wafer 200 is lower than 550° C., the reduction by supplying the H2 gas in the present step will be incomplete. Specifically, a film (in which a substance such as oxygen (O) and chlorine (Cl) contained in the Mo-containing film remains) may be formed. Further, when the temperature of the wafer 200 is higher than 590° C., the adsorption of molybdenum (Mo) is inhibited by the reaction by-products generated by supplying the H2 gas in the present step, and a film-forming rate becomes slow. Moreover, a resistivity of the film (that is, the Mo-containing film) increases.

That is, the temperature of the wafer 200 is adjusted within a range of 550° C. or higher and 590° C. or lower in a state where the H2 gas serving as the reducing gas is supplied to the wafer 200. Further, by supplying the H2 gas in a state where the temperature of the wafer 200 is adjusted within the range of 550° C. or higher and 590° C. or lower, it is possible to promote the reduction by supplying the H2 gas and it is also possible to improve a reactivity. Therefore, it is possible to promote the adsorption of molybdenum (Mo), and it is also possible to increase the film-forming rate. Further, by supplying the H2 gas in a state where the temperature of the wafer 200 is elevated within the range of 550° C. or higher and 590° C. or lower, it is possible to reduce the substance such as oxygen (O) and chlorine (Cl) remaining in the first Mo-containing film. Thereby, it is possible to remove the substance such as oxygen (O) and chlorine (Cl) from the first Mo-containing film, thereby forming the Mo-containing film whose resistance is low.

### <Residual Gas Removing Step S24>

After the Mo-containing layer is formed, the valve 324 of the gas supply pipe 320 is closed to stop the supply of the reducing gas. Then, the residual gas remaining in the process chamber 201 such as the residual reducing gas which did not react or which contributed to the formation of the Mo-containing layer and the reaction by-products are removed out of the process chamber 201 in substantially the same manners as in the step S14 described above. That is, the process chamber 201 is purged.

### <Performing a Predetermined Number of Times>

By performing a cycle (in which the step S21 through the step S24 described above are sequentially performed in this order) at least once (that is, a predetermined number of times (m times)), as shown in FIG. 5C, the second Mo-containing film of a predetermined thickness (for example, from 10 nm to 20 nm) is formed on the wafer 200 where the first Mo-containing film is formed on the surface thereof. That is, the second Mo-containing film of the predetermined thickness is formed on the first Mo-containing film. It is preferable that the cycle described above is repeatedly performed a plurality number of times. The second Mo-containing film formed by the present step is not in contact with the AlO film serving as the base film, and is formed on the first Mo-containing film capable of suppressing the diffusion of aluminum (Al) from the AlO film serving as the base film. Therefore, the second Mo-containing film is formed as a film capable of suppressing the diffusion of aluminum (Al).

### <After-Purge Step and Returning to Atmospheric Pressure Step>

The argon gas is supplied into the process chamber 201 through each of the gas supply pipes 510 and 520, and is exhausted through the exhaust pipe 231. The argon gas serves as the purge gas, so that the inner atmosphere of the process chamber 201 is purged with the inert gas. Thus, the residual gas remaining in the process chamber 201 or the reaction by-products remaining in the process chamber 201 is removed from the process chamber 201 (after-purge step). Thereafter, the inner atmosphere of the process chamber 201 is replaced with the inert gas (substitution by inert gas), and the inner pressure of the process chamber 201 is returned to a normal pressure (atmospheric pressure) (returning to atmospheric pressure step).

### <Boat Unloading Step and Wafer Discharging Step>

Thereafter, the seal cap 219 is lowered by the boat elevator 115 and the lower end opening of the outer tube 203 (that is, the lower end opening of the manifold 209) is opened. The boat 217 with processed wafers 200 charged therein is unloaded out of the outer tube 203 through the lower end opening of the outer tube 203 (boat unloading step). Then, the processed wafers 200 are discharged (transferred) out of the boat 217 (wafer discharging step).

According to the present embodiments, the product of the temperature of the wafer 200 (that is, the first temperature) and the supply time of the reducing gas (that is, the first time duration) in the first Mo-containing film forming step described above is 9,000° C. min (that is, 450° C.×20 minutes=9,000° C. min). Further, the product of the temperature of the wafer 200 (that is, the second temperature) and the supply time of the reducing gas (that is, the second time duration) in the second Mo-containing film forming step described above is 580° C. min (that is, 580° C.×1 minute=580° C. min). That is, the temperature of the wafer 200 and the supply time of the reducing gas in each of the first Mo-containing film forming step and the second Mo-containing film forming step are set such that the product of the second temperature and the second time duration in the second Mo-containing film forming step is set to be smaller than the product of the first temperature and the first time duration in the first Mo-containing film forming step. Thereby, it is possible to improve the throughput.

That is, by performing the first Mo-containing film forming step in the substrate processing of the present embodiments of the present disclosure, the first Mo-containing film capable of suppressing the diffusion of aluminum (Al) from the AlO film serving as the base film is formed on the wafer 200 where the AlO film is formed on the surface thereof. Thereafter, by performing the second Mo-containing film forming step, the second Mo-containing film is formed on the wafer 200 at a high growth rate by increasing the reactivity with the reducing gas by elevating the temperature of the wafer 200 where the first Mo-containing film is formed on the surface thereof. That is, the Mo-containing film constituted by the first Mo-containing film and the second Mo-containing film is formed on the wafer 200 where the AlO film is formed on the surface thereof. As a result, it is possible to form the Mo-containing film capable of improving the productivity while suppressing the diffusion of a metal element from a base metal film.

### (3) Effects According to Present Embodiments

According to the present embodiments, it is possible to obtain one or more of the following effects.
(a) It is possible to improve the productivity while suppressing the diffusion of the metal element from the base metal film into the Mo-containing film.
(b) It is possible to form the second Mo-containing film on the first Mo-containing film whose surface roughness is acceptable. That is, it is possible to improve the coverage (step coverage) by forming the second Mo-containing film on the first Mo-containing film whose flatness is sufficient. That is, it is possible to improve a filling performance of the Mo-containing film used for the control gate electrode of the NAND flash memory of a three-dimensional structure.
(c) It is possible to form the Mo-containing film with reduced substance such as oxygen (O) and chlorine (Cl).
(d)) It is possible to form the Mo-containing film whose resistivity is low.

### (4) Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

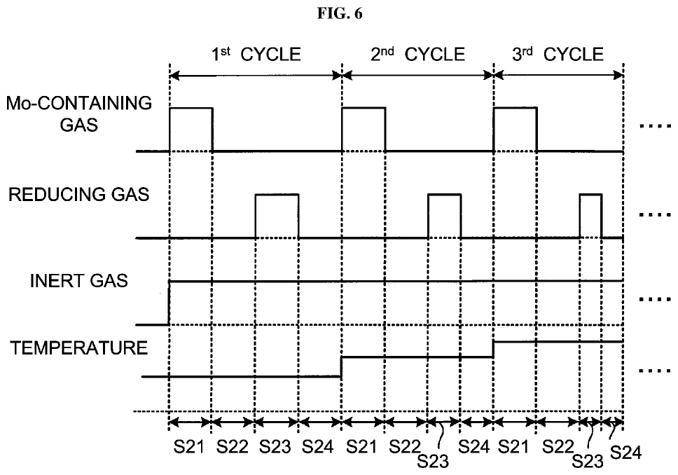

FIG. 6 is a diagram schematically illustrating a modified example of the second Mo-containing film forming step described above That is, according to the modified example, by performing the first Mo-containing film forming step described above, the first Mo-containing film is formed on the wafer 200. Thereafter, the second Mo-containing film forming step is performed a plurality of times after elevating the temperature of the wafer 200. Herein, the temperature of the wafer 200 is more raised and the supply time of the reducing gas in the step S23 is further shortened as the cycle of the second Mo-containing film forming step is repeated more and more. Even in such a case, it is possible to obtain substantially the same effects as described above for the substrate processing shown in FIG. 4.

For example, the embodiments described above are described by way of an example in which the MoO2Cl2 gas is used as the Mo-containing gas. However, the technique of the present disclosure is not limited thereto.

For example, the embodiments described above are described by way of an example in which the H2 gas is used as the reducing gas. However, the technique of the present disclosure is not limited thereto.

For example, the embodiments described above are described by way of an example in which the pressure and temperature adjusting step is performed before the second Mo-containing film forming step. However, the technique of the present disclosure is not limited thereto. For example, the pressure and temperature adjusting step and the second Mo-containing film forming step may be performed partially in parallel. Thereby, it is possible to form the Mo-containing film in the pressure and temperature adjusting step as well. As a result, it is possible to increase the thickness of the film (that is, the Mo-containing film). That is, it is possible to further improve the throughput (manufacturing throughput). Such a configuration is particularly effective in a single wafer type substrate processing apparatus configured to process wafers 200 one by one. This is because, the throughput is lowered in the single wafer type substrate processing apparatus where a temperature adjusting step should be performed for each wafer 200 (substrate).

For example, the embodiments described above are described by way of an example in which a vertical batch type substrate processing apparatus configured to simultaneously process a plurality of substrates is used to perform the substrate processing for the formation of the film. However, the technique of the present disclosure is not limited thereto. For example, the technique of the present disclosure may be preferably applied when the single wafer type substrate processing apparatus configured to process one or several substrates at a time is used to perform the substrate processing for the formation of the film.

Subsequently, examples according to the present embodiments will be described. However, the technique of the present disclosure is not limited thereto.

### (5) Examples

### First Example

The throughput of the Mo-containing film formed on the substrate (wafer 200) by the substrate processing according to the present embodiments (that is, the throughput of the Mo-containing film according to a first example) and the throughput of the Mo-containing film formed on the substrate (wafer 200) by a substrate processing according to a comparative example are compared.

According to the first example, the wafer 200 where the AlO film is formed on the surface thereof is subjected to 25 cycles of the first Mo-containing film forming step at 450° C. Thereafter, the wafer 200 is heated to 580° C. Then, the wafer 200 is subjected to 264 cycles of the second Mo-containing film forming step. That is, the Mo-containing film with is formed with a thickness of 200 Å on the wafer 200 in two stages. The supply time of the reducing gas is set to 20 minutes in the first Mo-containing film forming step and to 1 minute in the second Mo-containing film forming step.

According to the comparative example, the wafer 200 where the AlO film is formed on the surface thereof is subjected to 300 cycles of the first Mo-containing film forming step at 450° C. Thereby, the Mo-containing film is formed with a thickness of 200 Å on the wafer 200. The supply time of the reducing gas is set to 20 minutes.

The throughput of the Mo-containing film formed on the wafer 200 by using the substrate processing to according to the first example is about three times the throughput of the Mo-containing film formed on the wafer 200 by using the substrate processing according to the comparative example.

That is, by forming the Mo-containing film on the wafer 200 by the substrate processing according to according to the first example, the throughput is tripled as compared with a case where the Mo-containing film is formed on the wafer 200 by the substrate processing according to the comparative example, and the number of wafers 200 processed per hour increases. That is, it is confirmed that an improvement in the productivity of 3 times or more can be expected.

### Second Example

Subsequently, by using a secondary ion mass spectrometry (abbreviated as “SIMS”), a distribution of each element contained in the Mo-containing film in a depth direction is analyzed. For the analysis, a Mo-containing film according to the present embodiments (i.e., a second example) is formed by the substrate processing according to the second example, and another Mo-containing film according to a comparative example is formed by the substrate processing according to the comparative example.

According to the comparative example, the wafer 200 where the AlO film is formed on the surface thereof is subjected to 250 cycles of the first Mo-containing film forming step at 550° C. Thereby, the Mo-containing film is formed on the wafer 200.

It is confirmed that the diffusion from the AlO film serving as the base film can be suppressed in the Mo-containing film formed on the wafer 200 by the substrate processing according to the second example.

It is also confirmed that aluminum (Al) is diffused to the vicinity of the surface of the Mo-containing film formed on the wafer 200 by the substrate processing according to the comparative example, and that chlorine (Cl) and oxygen (O), which inhibit an adsorption of molybdenum (Mo), are also present.

That is, it is confirmed that the diffusion of aluminum (Al) from the AlO film serving as the base film can be suppressed in the Mo-containing film formed by elevating the temperature to 580° C. after performing the first Mo-containing film forming step at 450° C. (that is, the Mo-containing film formed by the substrate processing according to the second example) as compared with a case where the Mo-containing film is formed by uniformly heating the wafer 200 at 550° C. (that is, the Mo-containing film formed by the substrate processing according to the comparative example). In other words, it is confirmed that the diffusion of aluminum (Al) from the AlO film serving as the base film can be suppressed by forming the Mo-containing film on the AlO film by the substrate processing according to the second example.

### Third Example

Intensity distributions of aluminum (Al) in the depth direction in each Mo-containing film respectively formed by heating the wafer 200 to 450° C., 475° C. and 500° C. are compared.

As a result, in the Mo-containing film formed by heating the wafer 200 to 450° C., it is confirmed that aluminum (Al) is diffused up to about 2.5 nm from an interface with the AlO film serving as the base film. Further, in the Mo-containing film formed by heating the wafer 200 to 475° C., it is confirmed that aluminum (Al) is diffused up to about 3 nm from the interface with the AlO film serving as the base film. In addition, in the Mo-containing film formed by heating the wafer 200 to 500° C., it is confirmed that aluminum (Al) is diffused up to about 5 nm from the interface with the AlO film serving as the base film. That is, it is confirmed that, by adjusting the temperature of the wafer 200 in the substrate processing and the thickness of the first Mo-containing film formed on the AlO film, the diffusion of aluminum (Al) from the AlO film serving as the base film to the Mo-containing film can be suppressed.

That is, it is confirmed that, by forming the first Mo-containing film with a predetermined thickness while setting (adjusting) the temperature of the heater 207 in the first Mo-containing film forming step of the substrate processing described above such that the temperature of the wafer 200 reaches and is maintained at the temperature within the range equal to or higher than 445° C. and equal to or lower than 505° C., the diffusion of aluminum (Al) from the AlO film serving as the base film to the Mo-containing film can be suppressed.

According to some embodiments of the present disclosure, it is possible to improve the productivity while suppressing the diffusion of the metal element from the base metal film (underlying film) of the molybdenum-containing film.

What is claimed is:

1. A substrate processing method comprising:
(a) adjusting a temperature of the substrate to a first temperature;
(b) forming a first molybdenum-containing film on the substrate by performing:
(b1) supplying a molybdenum-containing gas to the substrate; and
(b2) supplying a reducing gas to the substrate for a first time duration,
wherein (b1) and (b2) are performed one or more times after performing (a);
(c) adjusting the temperature of the substrate to a second temperature after performing (b); and
(d) forming a second molybdenum-containing film on the first molybdenum-containing film by performing:
(d1) supplying the molybdenum-containing gas to the substrate; and
(d2) supplying the reducing gas to the substrate for a second time duration,
wherein (d1) and (d2) are performed one or more times after performing (c).

2. The method of claim 1, wherein the second temperature is higher than the first temperature, and the second time duration is shorter than the first time duration.

3. The method of claim 1, wherein the second temperature is equal to or higher than 550° C. and equal to or lower than 590° C.

4. The method of claim 1, wherein the first temperature is equal to or higher than 445° C. and equal to or lower than 505° C.

5. The method of claim 4, wherein the first time duration is equal to or longer than 10 minutes and equal to or shorter than 30 minutes, and the second time duration is equal to or longer than 10 seconds and equal to or shorter than 5 minutes.

6. The method of claim 1, wherein the first temperature, the second temperature, the first time duration and the second time duration are respectively set such that a product of the second temperature and the second time duration is smaller than a product of the first temperature and the first time duration.

7. The method of claim 1, wherein (c) is performed under an inert gas atmosphere.

8. The method of claim 7, wherein the inert gas comprises a rare gas.

9. The method of claim 8, wherein the rare gas comprises argon gas.

10. The method of claim 1, wherein (c) is performed in a state where the reducing gas is supplied to the substrate.

11. The method of claim 10, wherein the reducing gas comprises a hydrogen-containing gas.

12. The method of claim 11, wherein the hydrogen-containing gas comprises hydrogen gas.

13. The method of claim 1, wherein (c) is performed at a pressure higher than a pressure in (b) and a pressure in (d).

14. The method of claim 1, wherein (d1) and (d2) are performed one or more times while adjusting the temperature of the substrate to the second temperature in (c).

15. A method of manufacturing a semiconductor device, comprising the method of claim 1.

16. A non-transitory computer-readable recording medium storing a program that causes a substrate processing apparatus, by a computer, to perform:
(a) adjusting a temperature of a substrate to a first temperature;
(b) forming a first molybdenum-containing film on the substrate by performing:
(b1) supplying a molybdenum-containing gas to the substrate; and
(b2) supplying a reducing gas to the substrate for a first time duration,
wherein (b1) and (b2) are performed one or more times after performing (a);
(c) adjusting the temperature of the substrate to a second temperature after performing (b); and
(d) forming a second molybdenum-containing film on the first molybdenum-containing film by performing:
(d1) supplying the molybdenum-containing gas to the substrate; and
(d2) supplying the reducing gas to the substrate for a second time duration,
wherein (d1) and (d2) are performed one or more times after performing (c).

17. A substrate processing apparatus comprising:
a heater capable of adjusting temperature of a substrate;
a molybdenum-containing gas supplier through which a molybdenum-containing gas is supplied to the substrate;
a reducing gas supplier through which a reducing gas is supplied to the substrate; and
a controller configured to be capable of controlling the heater, the molybdenum-containing gas supplier and the reducing gas supplier to perform:
(a) adjusting a temperature of the substrate to a first temperature;
(b) forming a first molybdenum-containing film on the substrate by performing:
(b1) supplying the molybdenum-containing gas to the substrate; and
(b2) supplying the reducing gas to the substrate for a first time duration,
wherein (b1) and (b2) are performed one or more times after performing (a);
(c) adjusting the temperature of the substrate to a second temperature after performing (b); and
(d) forming a second molybdenum-containing film on the first molybdenum-containing film by performing:
(d1) supplying the molybdenum-containing gas to the substrate; and
(d2) supplying the reducing gas to the substrate for a second time duration,
wherein (d1) and (d2) are performed one or more times after performing (c).
